(19) United States
(12) Patent Application Publication
(10) Pub. No.: US 2014/0177196 A1
(43) Pub. Date: Jun. 26, 2014

(54) Collapsible Protective Case for Electronic Devices with Incorporated Radiation Shielding

(71) Applicants: Alaey Kumar, Seattle, WA (US); Cary Subel, San Diego, CA (US)

(72) Inventors: Alaey Kumar, Seattle, WA (US); Cary Subel, San Diego, CA (US)

(21) Appl. No.: 13/958,334

(22) Filed: Aug. 2, 2013

Related U.S. Application Data
(60) Provisional application No. 61/679,657, filed on Aug. 3, 2012.

(51) Int. Cl. H05K 9/00

(52) U.S. Cl. CPC H05K 9/0052
USPC 361/816

(57) ABSTRACT

The present invention pertains generally to protective cases for laptops which collapses into a rigid pad or lap desk which blocks thermal and/or EMF radiation. Optionally the protective case may have a built-in electromagnetic field (EMF) radiation shield.

### CROSS REFERENCES TO RELATED APPLICATIONS

This application is a non-provisional patent application, which claims the benefit of priority from U.S. Provisional Application No. 61/679,657, filed Aug. 3, 2012, the entire contents of which are incorporated herein by reference.

### FIELD OF THE INVENTION

The present invention pertains generally to protective cases for electronic devices. More particularly, the present invention pertains to a protective case for a laptop computer with a built-in electromagnetic field (EMF) radiation barrier.

### BACKGROUND OF THE ART

As technology is becoming a bigger part of our everyday lives, there is an increasing concern for the associated consequences. Among those concerns is how the various types of EMF radiation, which consists of extremely low frequency (ELF), WiFi®, Radio Frequency (RF), etc., can affect a user's health. Research by several organizations such as the International Agency for Research on Cancer (IARC) confirmed the validity of this concern, particularly in regards to devices that are commonly in direct contact with a user's body like laptops, tablet computers and cell phones. The IARC stated extremely low-frequency (ELF) magnetic fields, which are created by computers, cell phones and many other electronic devices, are “possibly carcinogenic to humans” (see http://www.who.int/peh-emf/publications/factsheets/en/index.html for more information).

A simple experiment using a Gauss meter to detect EMF radiation shows that the levels emitted from the bottom of a laptop are, in some spots, significantly higher than what is recommended exposure. According to Dr. Warren Brodey, a former Research Scientist at the National Institute of Health (NIH) and Massachusetts Institute of Technology (MIT), exposure up to 2.5 milliGauss (mG) is considered safe, however higher values are not considered entirely safe and over 10 mG is considered unhealthy. Prolonged exposure to these excessive levels may be linked to certain brain diseases such as ALS, Parkinson's, MS, and Alzheimer's as well as childhood and adult cancers. Dr. David Carpenter, Dean of the School of Public Health, State University of New York believes it is likely that up to 30% of all childhood cancers result from exposure to EMFs. The Environmental Protection Agency (EPA) warns that there is reason for concern and advises prudent avoidance of EMF radiation.

There are several key ways to reduce the amount of radiation felt by the body. Examples include: 1) using an external keyboard, monitor and mouse with electronic devices as a means of increasing the distance between a user and the source of radiation, which in turn reduces the exposure to any radiation originating from the device; 2) using a bulky pad between the user and the device; and 3) wearing metal woven shielding garments, such as Belly Armor®. Unfortunately, many of these products only block RF radiation.

Presently available products include the HARApad™ Elite and the DefenderPad™ which are radiation shields that serve as a barrier and platform between the user and a laptop. However, these products are additional items that a user must carry with them for the sole purpose of using it as a shielding device. As such, the HARApad™ and the DefenderPad™ may not be the best solution for user's that must travel with and/or transport their electronic devices regularly. Also available to reduce radiation emissions from electronic devices are various shields for computer monitors, TV screens, and keyboards. Again, these products are not convenient for the user that must travel with and/or transport an electronic device. More extreme products for reducing exposure to radiation emissions include shielded gloves, headbands, aprons, hats, shirts, sweatshirts, sleeping bags and even tents. However, for many users it would not be practical to wear radiation shielding garments each time they must use an electronic device. Examples of patents covering some of these products are disclosed herein.

U.S. Pat. No. 8,205,744 to Tashjian discloses an EMF shielding device that folds over itself to form a brief case style carrying case for a laptop or notebook wherein the shield includes a plywood laminate wrapped in an optional magnetic field shielding material.

U.S. Pat. No. 5,124,889 to Humbert et al. discloses an electromagnetic shielding apparatus for cellular telephones and other electronic equipment, which reliably shields circuitry therein which is subject to electromagnetic interference from internally and externally generated electromagnetic signals.

U.S. Pat. No. 6,515,223 to Tashjian discloses a shielding device to protect cellular or cordless phone users from EMF comprising a flat internal flexible conductive sheath which is positioned on top of a flat non-conductive sheathing with a border of non-conductive sheathing extending outwardly thereabout.

In light of the above, it is an object of the present invention to provide the desired features described herein as well as additional advantages such as providing EMF emission shielding, particularly both RF and ELF, for electronic devices that is so convenient, effective and affordable that user's will actually want to the use it regularly.

### SUMMARY OF THE INVENTION

The present invention is directed to solving the deficiency in the art pertaining to the shielding of EMF radiation from portable electronic devices.

It is an object of the protective case to hold a portable electronic device. One of skill in the art would understand that the term “electronic device” as used herein includes, but is not limited to, laptop computers, tablet computers, cell phones, iPads®, iPods®, digital cameras, handheld devices such as Personal Digital Assistants (PDAs), portable gaming systems such as Gameboy® and PlayStation Portable (PSP®), or any portable electronic device that emits radiation.

It is an object of the protective case to protect and/or shield a user from the EMF radiation emitted from said portable electronic device during use. The term “use” as used herein includes not only when a user is actively engaged with said portable electronic device but also any time said device is powered on and emitting heat and/or EMF radiation. One of skill in the art would also understand that EMF radiation includes, but is not limited to, ELF, WiFi and RF types of emissions.

It is an object of the protective case to have at least one side that is capable of minimizing or even eliminating the amount of radiation exposure to a user's body in the direction of the protective case.

It is another object of the protective case to optionally have at least one side with anti-radiation material incorporated into the structure of the case.

It is another object of the protective case to serve as a carrying case for the electronic device when transporting said electronic device.

It is another object of the protective case to protect the enclosed electronic device from damage such as breakage or scratches when transporting said device.

It is yet another object of the protective case to provide a method for protecting a user from radiation emitted from a portable electronic device, the method comprising:

a) providing said user of an electronic device with a protective case capable of blocking thermal and/or electromagnetic field (EMF) radiation, said protective case comprising:
an external material that forms the outermost surface of said protective case wherein said protective case is further defined by at least:
   a back panel;
   a spine panel;
   a front panel; and
   at least two side panels;
wherein at least the front panel and/or the back panel is further comprised of a rigid layer; and further wherein openings formed at the intersection between the side panels and the spine panel facilitate the collapsing of said protective case into a pad;

b) inserting said electronic device inside said protective case when transporting and/or not actively using said electronic device;

c) removing said electronic device from said protective case when ready for use;

d) collapsing said protective case on itself to create a pad and/or lap desk; and

e) placing said collapsed protective case between said user and said electronic device during use of the electronic device by the user thereby creating a barrier against thermal and/or EMF radiation between the electronic device and the user.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1a illustrates a perspective view of the protective case.

FIG. 1b illustrates an exploded view of the protective case of FIG. 1a.

FIG. 2 illustrates a lateral cross-section of the assembled protective case of FIG. 1b.

FIG. 3 illustrates an exploded view of an alternate embodiment of the protective case.

FIG. 4 illustrates a lateral cross-section of the assembled protective case of FIG. 3.

FIG. 5 illustrates a perspective view of the openings formed at the intersection between the side panels and the spine panel of the protective case.

### DETAILED DESCRIPTION OF THE INVENTION

As used herein, the term “adjacent” means “next to” or within the same panel of the assembled protective case. For example, if the anti-radiation is adjacent to the external material it may be positioned directly next to the external material or in the alternative it may be within the same panel but separated from the external material by an intermediate layer.

As used herein, the term “panel” means the combination of one or more layers of various materials which together make up a specific panel of the protective case.

As used herein, the term “mu-metal” means a range of nickel-iron alloys that are notable for their high magnetic permeability, which may be composed of approximately 77% nickel, 16% iron, 5% copper and 2% chromium or molybdenum. The high permeability makes mu-metal useful for shielding against static or low-frequency magnetic fields such as extremely low frequency and radio frequency.

As used herein, the phrase “supple material” means any material that is flexible and pliant and capable of being bent or folded without creases, cracks or breaks and is further capable of returning to its original position as necessary.

As used herein, the phrase “stretchable material” means any material that is capable of extending or expanding in length and or width in response to a force. For example, stretchable sides of the protective case may expand to accommodate larger laptop computers or electronic devices.

Figures are not drawn to scale and are only provided to illustrate the instant invention. Embodiments of the present invention provide systems and methods for shielding a user from EMF radiation emitted from portable electronic devices. Although various embodiments of the present invention will be illustrated in terms of laptop computers, one of ordinary skill in the art will recognize that the present invention can be used for many electronic devices. The term “electronic device” as used herein includes, but is not limited to, laptop computers, tablet computers, cell phones, iPads®, iPods®, digital cameras, handheld devices such as Personal Digital Assistants (PDAs), portable gaming systems such as Gameboy® and PlayStation Portable (PSP®), or any portable electronic device that emits radiation.

Additionally, the shape and size of the protective case may vary to accommodate the type of portable electronic device. For example, the protective case may be in the form of a sleeve, a bag or a case that fully encloses the device. In one embodiment the protective case may have a closing mechanism, such as a zipper, Velcro®, or magnets. In another embodiment the protective case may not have a closing mechanism such as when the case is in the form of a sleeve. In still another embodiment the protective case has a flap that may serve as a mouse pad when said case is being used to protect a user from the radiation emitted from a laptop computer.

The various embodiments of the present invention provide a radiation barrier between an electronic device and the body of a user which also inherently blocks heat emitted from said electronic device. The anti-radiation material may consist of mu-metal or a roughly 80% nickel alloy (for example, Ni 80%, Fe 15%, Mo 5% plus trace amounts of S, C, Mn, Si, & P) magnetic shielding foil, or any other material that shields electromagnetic interference. One of ordinary skill in the art would recognize other materials that could be used to block other forms of radiation. It is also contemplated that materials could be combined to block more than one type of radiation. The external material may be comprised of vinyl, neoprene, leather or fabric, or any other desirable material. In a preferred embodiment the protective case has a rigid layer made of cardboard, plastic or any other material to add rigidity to the case and provide a surface upon which to place the anti-radiation material. In an alternative embodiment, the protective case may optionally have additional rigid layers. Also optional is a layer of soft padding such as cotton, wool, compressible material or any other material that may be used to provide padding. Also optional is a softer inner liner such as felt, suede or such other material to provide a soft surface to prevent scratching of the portable electronic device when placed inside the protective case. In one embodiment the sides of the case are comprised of an elastic material that allows the case to stretch to accommodate thicker laptop computers. Additionally, the sides allow the protective case to collapse fully on itself once the device is removed from the case effectively converting the protective case into a convenient pad and/or lap desk.

It is also contemplated that the protective case take the shape of a briefcase comprised of handles, shoulder straps, and pouches and/or compartments for other items such as pens, pads or paper. In one embodiment the briefcase may be collapsible to serve as a lap desk. In another embodiment the protective case may detach from the briefcase for use as a lap desk.

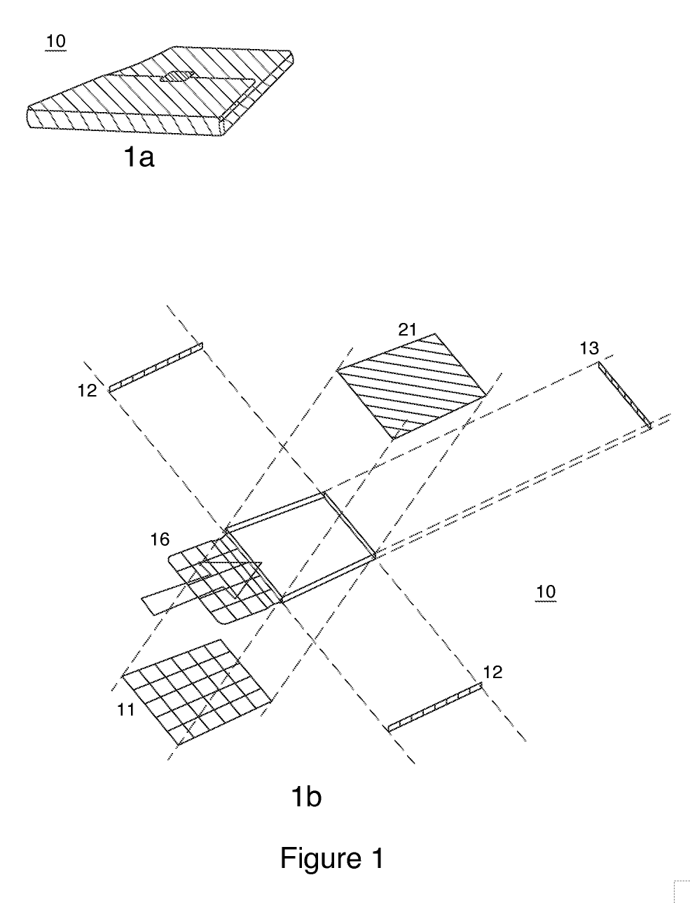

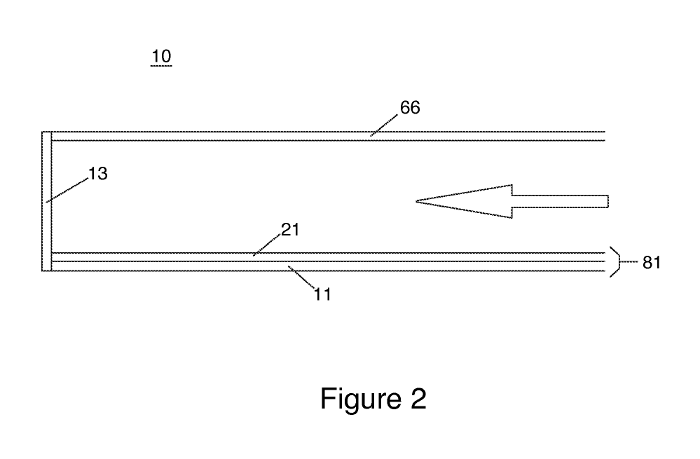

Reference is made to FIG. 1a which illustrates one embodiment of the protective case 10. The protective case 10 is further shown in an exploded view in FIG. 1b wherein for illustrative purpose the front panel of said protective case 10 is not shown. The protective case 10 has an external material that forms the outermost surface such that the protective case 10 is comprised of at least a back panel (81 seen in FIG. 2), a spine panel 13, and a front panel (not shown). Optionally, the case may have a flap panel 16. The protective case 10 additionally has at least one rigid layer 21 accompanied by an adjacent layer of anti-radiation material (not shown) that is located adjacent to the external material on at least one side, for example the external back layer 11, of said protective case 10. In an alternative embodiment, the at least one rigid layer 21 is not accompanied by anti-radiation material. In a preferred embodiment as shown, the protective case 10 also has two side panels 12 such that the protective case 10 encloses the portable electronic device securely inside said protective case 10 while providing openings formed at the intersection between the side panels and the spine panel of said protective case 10 which thereby facilitate the collapsing of the protective case 10. In particular, the sides and spine are made of a supple and/or stretchable material such that they fold inward or outward while the openings allow the folding sides and spine to not interfere with each other when in the collapsed state. In a preferred embodiment the side panels 12 are made from any supple material but are not stretchable. In a further preferred embodiment the side panels 12 are made from any supple material that is also stretchable.

Reference is made to FIG. 2 which illustrates a lateral cross-section of the assembled protective case of FIG. 1b. The protective case 10 has a back panel 81, a spine panel 13, a front panel 66 and at least one side panel (not shown). The back panel 81 is comprised of at least one rigid layer 21 accompanied by an adjacent layer of anti-radiation material (not shown) that is located adjacent to the external material on at least one side, for example the external back layer 11, of said protective case 10. In an alternative embodiment, the at least one rigid layer 21 is not accompanied by anti-radiation material. In this particular embodiment, the front panel 66 is comprised of a single layer of external material. In a preferred embodiment, said external back layer 11, said spine panel 13, and said front panel 66 are comprised of the same external material. In another embodiment said external back layer 11, said spine panel 13, and said front panel 66 may be comprised of one or more external materials. In yet another embodiment, said external back layer 11 and said front panel 66 are made from a first external material while said spine panel 13 and said side panel (not shown) are made from the same, second external material.

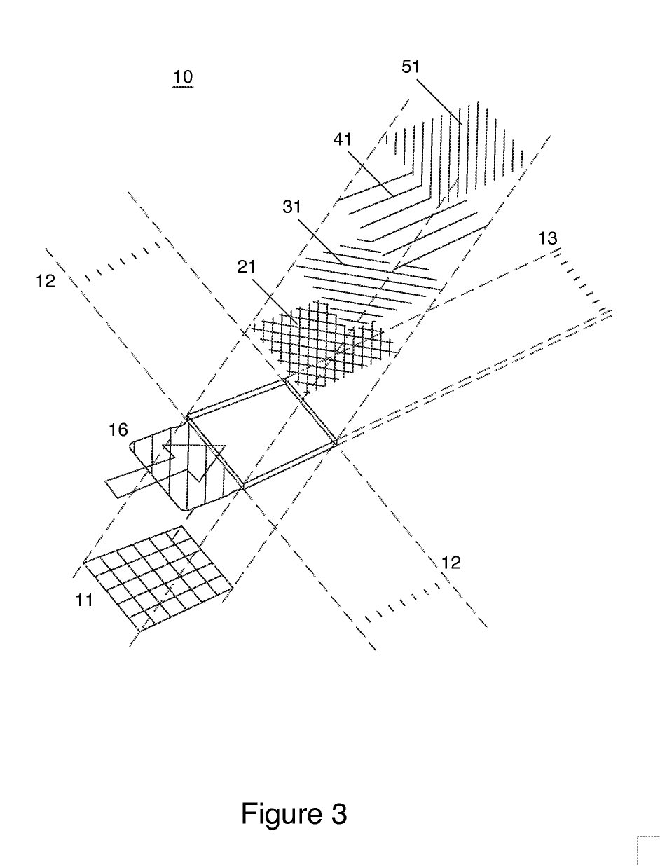

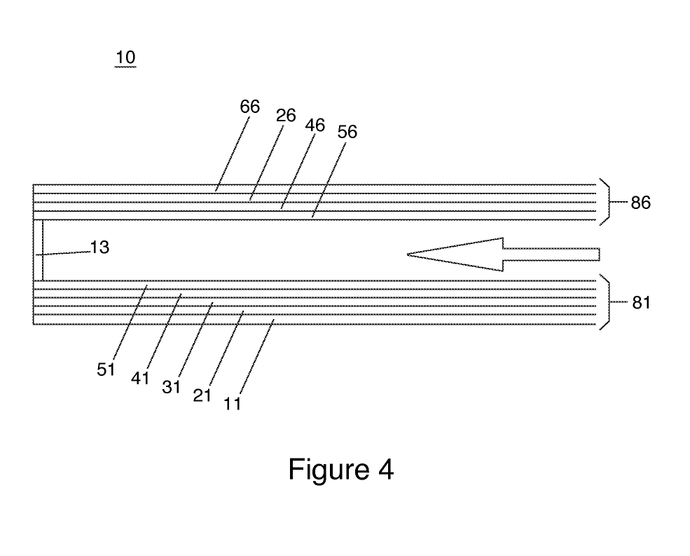

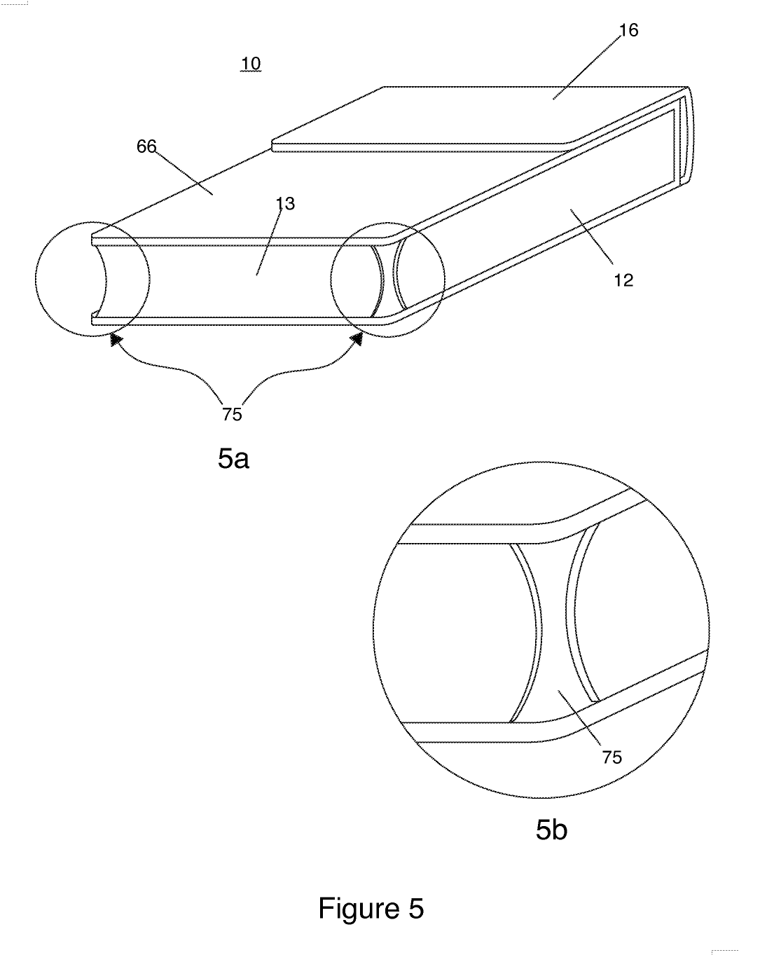

Reference is made to FIG. 3 which illustrates an exploded view of an alternate embodiment of the protective case 10 wherein for illustrative purpose the front panel of said protective case 10 is not shown. The protective case 10 has an external material that forms the outermost surface such that the protective case 10 is comprised of at least a back panel (81 seen in FIG. 4), a spine panel 13, and a front panel (not shown). Optionally, the case may have a flap panel 16. The protective case 10 additionally has one rigid layer 21 accompanied by an adjacent layer of anti-radiation material 31 that is located adjacent to the external material on at least one side, for example the external back layer 11, of said protective case 10. In an alternative embodiment, the at least one rigid layer 21 is not accompanied by anti-radiation material. In a preferred embodiment as shown the protective case 10 also has two side panels 12 such that the protective case 10 encloses the portable electronic device securely inside said protective case 10 while providing openings (described in FIG. 5) formed at the intersection between the side panels and the spine panel of said protective case 10 which thereby facilitate the collapsing of the protective case 10. In particular, the side panels 12 and spine panel 13 are made of a supple and/or stretchable material such that they fold inward or outward while the openings allow the folding sides 12 and spine 13 to not interfere with each other when in the collapsed state. In a preferred embodiment the side panels 12 are made from any supple material but are not stretchable. In a further preferred embodiment the side panels 12 are made from any supple material that is also stretchable. Optionally, each of said back panel 81 and said front panel (not shown) is further comprised of a rigid layer 21 which for said back panel 81 may be located between said external back layer 11 and a layer of anti-radiation material 31. The rigid layer 21 may be comprised of cardboard, plastic or any other material to provide additional rigidity to said protective case 10. Further optionally, each of said back panel 81 and said front panel (not shown) is further comprised of a padding layer 41. The padding layer 41 may be comprised of cotton, wool, compressible material or any other material to provide soft padding to said protective case 10. Still further optionally, each of said back panel 81 and said front panel (not shown) is further comprised of a liner layer 51. The optional liner layer 51 may be comprised of felt, suede or any other material to provide a soft surface for the inside of said protective case 10.

Reference is made to FIG. 4 which illustrates a lateral cross-section of the assembled protective case of FIG. 3. The protective case 10 has a back panel 81, a spine panel 13, a front panel 86 and at least one side panel (not shown). In this particular embodiment, the back panel 81 is further comprised of a rigid layer 21, a layer of anti-radiation material 31, a padding layer 41 and a back liner layer 51. In this particular embodiment, the front panel 86 is further comprised of a rigid layer 26, a padding layer 46 and a front liner layer 56.

Reference is made to FIG. 5 which illustrates openings formed at the intersection between the side panels and the spine panel of the assembled protective case of FIG. 1 and FIG. 3. In FIG. 5a, the protective case has a back panel (not shown), a spine panel 13, and a front panel 66. Also shown are one side panel 12 and optional flap 16. Once assembled the protective case 10 has openings formed at the intersection between the side panels and the spine panel 75 which facilitate the collapsing of the case for ease of use as a pad or lap desk. FIG. 5b illustrates a close-up view of the openings 75 when the protective case 10 is in the process of collapsing and spine panel 13 and side panel 12 are folding without interfering with each other.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

While the particular protective case as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A protective case for an electronic device which blocks thermal and/or electromagnetic field (EMF) radiation comprising:
an external material that forms the outermost surface of said protective case wherein said protective case is further defined by at least:
a back panel;
a spine panel;
a front panel; and
at least two side panels;
wherein at least the front panel and/or the back panel is further comprised of a rigid layer; and further wherein openings formed at the intersection between the side panels and the spine panel facilitate the collapsing of said protective case into a rigid pad.

2. The protective case of claim 1, wherein the panel including the rigid layer is further comprised of a layer of anti-radiation material that is integrated into the at least one panel of said protective case.

3. The protective case of claim 1, wherein the at least two side panels are made from a supple material.

4. The protective case of claim 1, wherein said spine panel and/or said two side panels are shorter than the entire width and/or length of the case.

5. The protective case of claim 2, wherein said spine panel and/or said two side panels are shorter than the entire width and/or length of the case.

6. The protective case of claim 2, wherein said layer of anti-radiation material is any material that shields or blocks any type of EMF radiation.

7. The protective case of claim 2, wherein said layer of anti-radiation material is mu-metal.

8. The protective case of claim 2, wherein said electronic device is a laptop computer.

9. The protective case of claim 3, wherein the at least two side panels are also stretchable.

10. The protective case of claim 1, wherein each of said back panel and/or said front panel is further comprised of:
at least one padding layer; and
at least one liner layer.

11. The protective case of claim 2, wherein each of said back panel and/or said front panel is further comprised of:
at least one padding layer; and
at least one liner layer.

12. The protective case of claim 1, wherein said back panel, said spine panel, said front panel and said at least two side panels are made from the same material.

13. The protective case of claim 2, wherein said back panel, said spine panel, said front panel and said at least two side panels are made from the same material.

14. The protective case of claim 1, wherein said back panel and said front panel are made from a first material and said spine panel and said at least two side panels are made from a second material.

15. The protective case of claim 2, wherein said back panel and said front panel are made from a first material and said spine panel and said at least two side panels are made from a second material.

16. The protective case of claim 1, wherein said protective case is essentially a sleeve for carrying said electronic device.

17. The protective case of claim 14, wherein said protective case is essentially a sleeve for carrying said electronic device.

18. A method for protecting a user from thermal and/or EMF radiation emitted from electronic devices, said method comprising:
a) providing said user of an electronic device with a protective case capable of blocking thermal and/or electromagnetic field (EMF) radiation, said protective case comprising:
an external material that forms the outermost surface of said protective case wherein said protective case is further defined by at least:
a back portion;
a spine portion;
a front portion; and
at least two side portions;
wherein at least the front panel and/or the back panel is further comprised of a rigid layer; and further wherein openings formed at the intersection between the side panels and the spine panel facilitate the collapsing of said protective case into a rigid pad;
b) inserting said electronic device inside said protective case when transporting and/or not actively using said electronic device;
c) removing said electronic device from said protective case when ready for use;
d) collapsing said protective case on itself to create a pad; and
e) placing said collapsed protective case between said user and said electronic device during use of the electronic device by the user thereby creating a barrier against radiation between the electronic device and the user.

19. The method of claim 18, wherein the panel including the rigid layer is further comprised of a layer of anti-radiation material that is integrated into the at least one panel of said protective case.

20. The method of claim 18, wherein said anti-radiation material is mu-metal.

21. The method of claim 18, wherein said anti-radiation material is any material that shields or blocks any type of EMF radiation.

22. The method of claim 18, wherein said electronic device is a laptop computer.
